(19) United States
(12) Patent Application Publication
(10) Pub. No.: US 2015/0194305 A1
(43) Pub. Date: Jul. 9, 2015

(54) SEMICONDUCTOR DEVICE AND METHOD OF MANUFACTURING THE SAME

(71) Applicant: KABUSHIKI KAISHA TOSHIBA, Minato-ku (JP)

(72) Inventor: Junichi SHIBATA, Yokkaichi (JP)

(73) Assignee: KABUSHIKI KAISHA TOSHIBA, Minato-ku (JP)

(21) Appl. No.: 14/204,464

(22) Filed: Mar. 11, 2014

Related U.S. Application Data
(60) Provisional application No. 61/925,291, filed on Jan. 9, 2014.

(51) Int. Cl. H01L 21/02; H01L 29/78; H01L 29/66; H01L 21/283

(52) U.S. Cl. CPC H01L 21/02274; H01L 21/283; H01L 21/02063; H01L 21/02068; H01L 29/78; H01L 29/66477

(57) ABSTRACT

A semiconductor device includes an insulating layer having a trench; a first insulating film formed only along an upper portion of the trench, a thickness of the first insulating film increasing in an upward direction from a bottom portion of the trench. The semiconductor device further includes a first conductor layer formed in the trench, a side surface of the first conductor contacting the insulating layer and the first insulating film.

### CROSS-REFERENCE TO RELATED APPLICATION(S)

This application is based upon and claims the benefit of priority from U.S. Provisional Patent Application No. 61/925,291, filed on, Jan. 9, 2014 the entire contents of which are incorporated herein by reference.

### FIELD

Embodiments disclosed herein generally relate to a semiconductor device and a method of manufacturing the same.

### BACKGROUND

In recent years, the wirings of a NAND flash memory, which is one example of a semiconductor device, are being shrunk. In such circumstances, it may be difficult to ensure a sufficient distance between the contact holes and wirings.

### BRIEF DESCRIPTION OF THE DRAWINGS

FIG. 1 is one example of an equivalent circuit representation of a part of a memory cell array formed in a memory cell region of a NAND flash memory device.

FIG. 2 is a layout pattern of the memory cell region in part.

FIG. 3 is one example of a vertical cross sectional view schematically illustrating the structure and the manufacturing method of a NAND Flash memory device of the present embodiment.

FIGS. 4 to 8 illustrate the manufacturing method of the NAND flash memory device of the present embodiment and is one example of a vertical cross sectional view illustrating the cross sectional structure of one phase of the manufacturing process flow.

FIG. 9 is one example of a vertical cross sectional view illustrating a modified example of the NAND flash memory device of the present embodiment.

FIG. 10 is one example of a vertical cross sectional view illustrating another modified example of the NAND flash memory device of the present embodiment.

### DETAILED DESCRIPTION

In one embodiment, a semiconductor device includes an insulating layer having a trench; a first insulating film formed only along an upper portion of the trench, a thickness of the first insulating film increasing in an upward direction from a bottom portion of the trench. The semiconductor device further includes a first conductor layer formed in the trench, a side surface of the first conductor contacting the insulating layer and the first insulating film.

### Embodiment

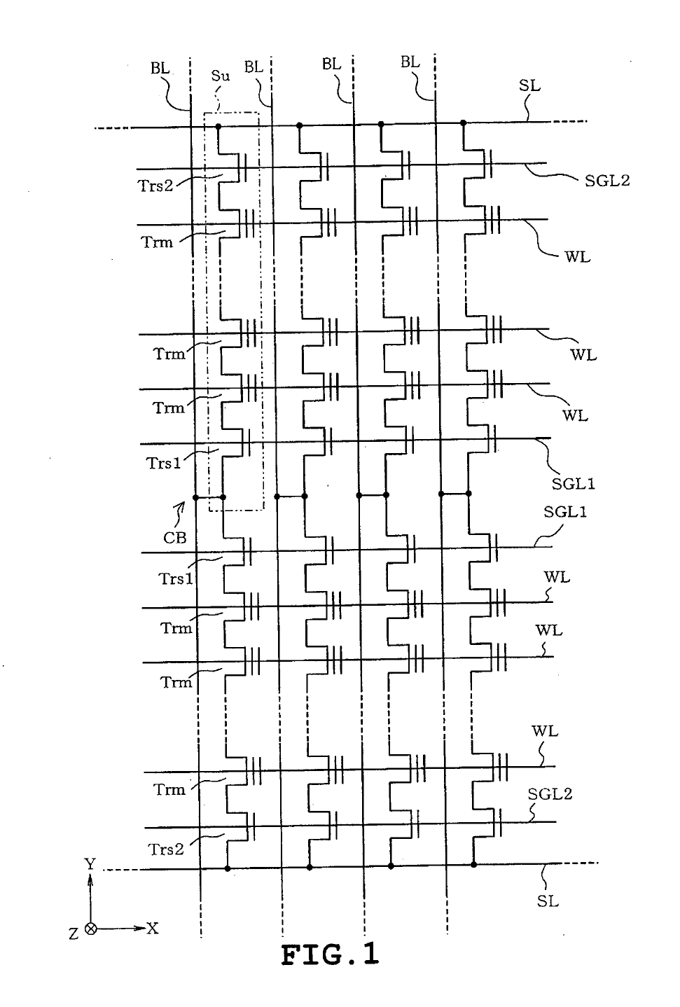

A first embodiment of a semiconductor device is described hereinafter through a NAND flash memory device application with references to FIGS. 1 to 8. In the following description, elements that are identical in function and structure are identified with identical reference symbols. The drawings are not drawn to scale and thus, do not reflect the actual measurements of the features such as the correlation of thickness to planar dimensions and the relative thickness of different layers. Further, directional terms such as up, down, lower, left, and right are used in a relative context with an assumption that the surface, on which circuitry is formed, of the later described semiconductor substrate faces up. Thus, the directional terms do not necessarily correspond to the directions based on gravitational acceleration. In the following description, XYZ orthogonal coordinate system is used for ease of explanation. In the coordinate system, the X direction and the Y direction indicate directions parallel to the surface of a semiconductor substrate and are orthogonal to one another. The X direction indicates the direction in which word line WL extends, and the Y direction, being orthogonal to the X direction, indicates the direction in which bit line BL extends. The embodiment is described based on NAND flash memory which is one example of a nonvolatile semiconductor storage device and references to interchangeable technologies will be made whenever applicable.

First, a description will be given on the structures of a NAND flash memory device of the present embodiment.

FIG. 1 is one example of an equivalent circuit representation of a part of a memory cell array formed in a memory cell region of a NAND flash memory device.

The memory cell array of the NAND flash memory device includes NAND cell units Su arranged in rows and columns. NAND cell unit Su comprises a multiplicity of series connected memory-cell transistors Trm (such as 32 in number) connected to a couple of select gate transistors Trs. The adjacent memory-cell transistors Trm within NAND cell unit Su share their source/drain regions.

Memory-cell transistors Trm aligned in the X direction as viewed in FIG. 1 (corresponding to word line direction, gate width direction) are interconnected by a common word line (control gate line). Select gate transistors Trs1 aligned in the X direction as viewed in FIG. 1 are interconnected by common select gate line SGL1 and select gate transistors Trs2 are interconnected by common select gate line SGL2. The drain of each select gate transistor Trs1 is connected to bit line contact CB. Bit line contact CB is connected to bit line BL extending in the Y direction (corresponding to gate length direction, bit line direction) orthogonal to the X direction as viewed in FIG. 1. The source of each select gate transistor Trs2 is connected to source line SL extending in the X-direction as viewed in FIG. 1.

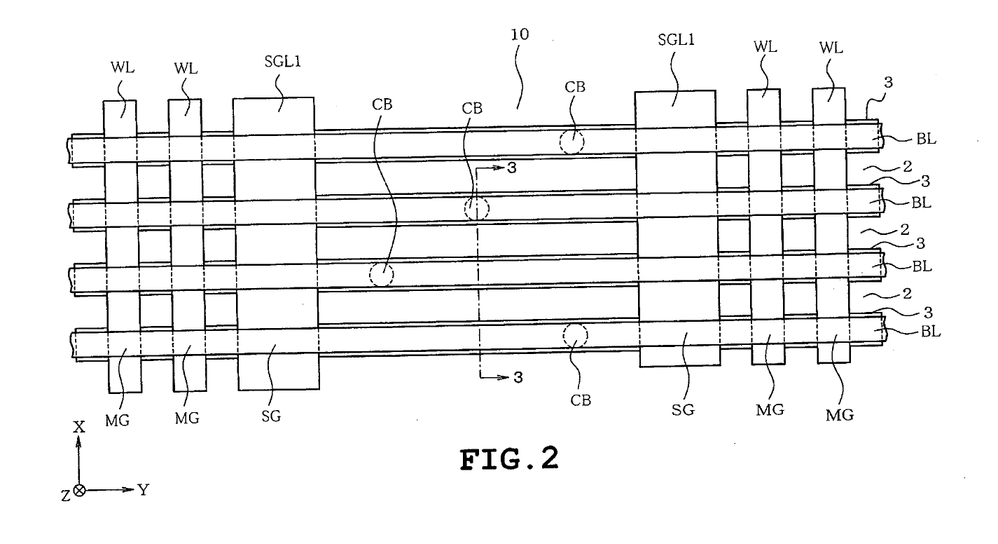

FIG. 2 is a view partially illustrating the layout of memory cell region. In FIG. 2, STIs serving as element isolation region 2 run in the Y direction as viewed in FIG. 2 of semiconductor substrate 10 one example of which may be a silicon substrate. Element isolation regions 2 are spaced from one another by a predetermined spacing in the X direction as viewed in FIG. 2. As a result, element regions 3, running in the Y-direction as viewed in FIG. 2, are divided in the X direction as viewed in FIG. 2. Word lines WL of memory-cell transistors extend in the direction orthogonal to element region 3 (the X direction as viewed in FIG. 2). Word lines WL are spaced from one another in the Y direction by a predetermined spacing as viewed in FIG. 2. Word lines WL and element regions 3 are latticed and 32 word lines WL, for example, form a single NAND string.

A pair of select gate lines SGL1, SGL2 is formed at each end of the NAND string. The pair select gate lines SGL1 is the drain side and the pair of select gate lines SGL2 is the source side. In each of element regions 3 located between the pair of select gate lines SGL1, bit line contact CB is formed. Bit line contacts CB adjacent in the X direction are disposed so as to be displaced in the bit line direction (Y direction). Further, 3 bit line contacts CB adjacent in the X direction are grouped together and this group is repeated in the X direction to exhibit a so called triple zigzag. Alternatively, the repeating group may be formed of 2 bit line contacts CB or 4 or more bit line contacts CB.

Above the element region intersecting with word line WL, gate electrode MG of the memory-cell transistor is formed. Above the element region intersecting with select gate line SGL1, SGL2, gate electrode SG of select gate transistor is formed.

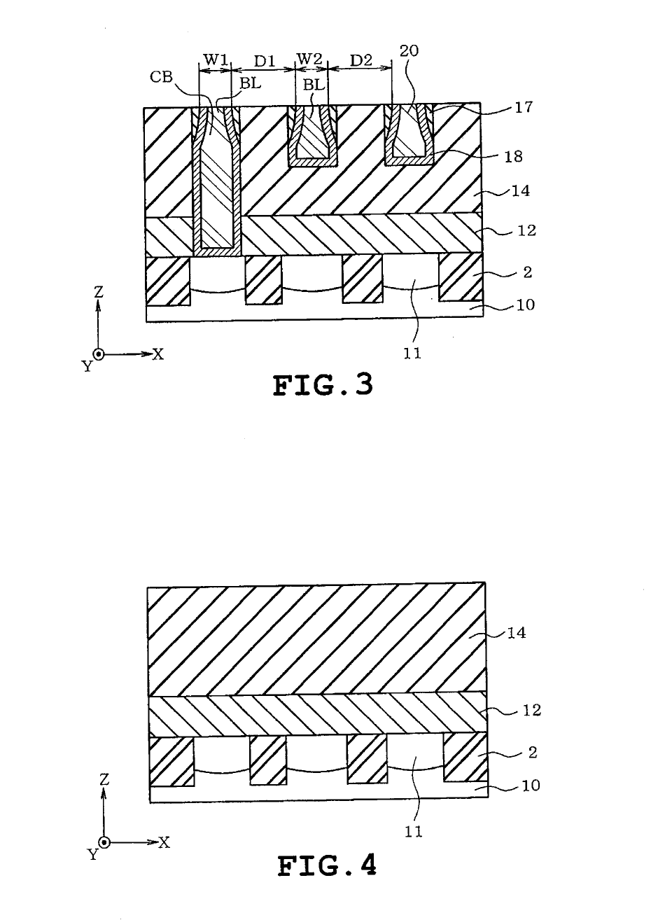

The structures of the present embodiment will be described in detail with reference to FIG. 3. FIG. 3 is one example of a vertical cross sectional view schematically illustrating the structures of a NAND flash memory device of the present embodiment. FIG. 3 is one example of a view schematically illustrating a cross sectional structure taken along line 3-3 of FIG. 2. The cross sectional structure represents the region in which the drain-side bit line contact CB is formed.

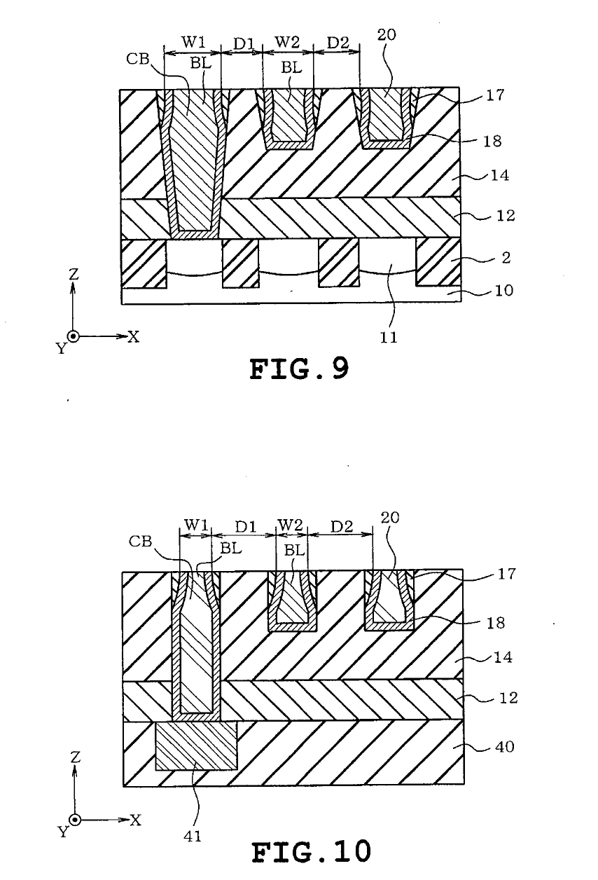

Referring to FIG. 3, element isolation region 2 is formed in an upper portion of semiconductor substrate 10. Semiconductor substrate 10 is delineated into element regions by element isolation region 2 and impurity region 11 is formed in the surface of the element region. Element isolation region 2 is formed of a silicon oxide film, for example. Impurities such as phosphorous or arsenic are introduced into impurity region 11 and thus, impurity region 11 serves as a conductor layer which is electrically conductive. Impurity region 11 formed by introducing impurities into semiconductor substrate 10 is given as one example of a conductor layer. However, the conductor layer is not limited to impurity region 11 but may be a wiring layer 41 in an insulating layer 40 above the semiconductor substrate 10 as shown FIG. 10 (for example, a gate electrode of a MOS transistor).

Insulating film 12 is provided above semiconductor substrate 10. A silicon nitride film may be used, for example, as insulating film 12. Interlayer insulating layer 14 is provided above insulating film 12. A silicon oxide film may be used, for example, as interlayer insulating layer 14.

Bit line BL includes barrier metal 18 and metal film 20. A trench is formed into interlayer insulating layer 14 so as to extend in the Y direction as viewed in the figures. Bit line BL is formed by filling the trench with barrier metal 18 and metal film 20. Barrier metal 18 may be formed of, for example, a stack of titanium (Ti)/titanium nitride (TiN) films, a stack of tantalum (Ta)/tantalum nitride (TaN) films, a stack of tantalum nitride/ruthenium (Ru) films, tantalum, tantalum nitride, titanium nitride, cobalt-tungsten-phosphorous (CoWP), or the like. Metal film 20 may be formed of, for example, tungsten (W), copper (Cu), molybdenum (Mo), or the like.

Sidewall films 17 are formed along the upper side surface of the inner wall of the wiring trench of bit line BL. A silicon nitride film may be used, for example, for sidewall films 17. In the cross section taken along the width direction of bit line BL (the X direction in FIG. 3), sidewall films 17 are formed only along the upper side surface of the inner sidewall of the wiring trench of bit line BL. The thickness of sidewall films 17 becomes thicker toward the upward direction, in other words, toward the upward direction in the Z direction as viewed in FIG. 3. Further, in the cross section taken along the width direction of bit line BL (the X direction in FIG. 3), the outline of sidewall films 17 is curved and the upper end portion (uppermost portion) has the maximum thickness. Sidewall films 17 may be described as being formed in the shape of a collar along the side surface of interlayer insulating layer 14.

Thus, in the cross section taken along the width direction of bit line BL (the X direction in FIG. 3), the conductor layer portion (barrier metal 18 and metal film 20) of bit line BL is shaped so as to be narrowed toward its upper portion (the Z direction as viewed in FIG. 3). In other words, in the cross section taken along the width direction of bit line BL (the X direction in FIG. 3), the width of the upper portion of bit line BL is reduced toward the upper portion. The side surfaces of bit line BL contact the side surfaces of interlayer insulating layer 14 and sidewall films 17. Further, the width in the X direction of the portion of bit line BL contacting the side surface of sidewall films 17 is narrowed.

As shown in FIG. 2, the planar pattern of bit line contact CB has a round shape or an oval shape in which the major axis is taken along the Y direction. Each of bit line contacts CB may be formed in one with bit line BL extending in the Y direction as viewed in FIG. 2.

As shown in FIG. 3, bit line contact CB extends from the surface of interlayer insulating layer 14 to the surface of semiconductor substrate 10 through insulating film 12. Bit line contact CB includes barrier metal 18 and metal film 20. Bit line contact CB is filled with barrier metal 18 and metal film 20. Barrier metal 18 may be formed of, for example, a stack of titanium (Ti)/titanium nitride (TiN) films, a stack of tantalum (Ta)/tantalum nitride (TaN) films, a stack of tantalum nitride/ruthenium (Ru) films, tantalum, tantalum nitride, titanium nitride, cobalt-tungsten-phosphorous (CoWP), or the like. Metal film 20 may be formed of, for example, tungsten (W), copper (Cu), molybdenum (Mo), or the like.

Sidewall films 17 are formed along the upper side surface of the inner wall of the contact hole of bit line contact CB. Sidewall film 17 is formed of an insulating film and is formed, for example, of a silicon nitride film.

Sidewall films 17 are formed along the upper side surface of the inner sidewall of the contact hole of bit line contact CB. Sidewall films 17 are formed only along the upper side surface of the inner sidewall of the contact hole of bit line contact CB. The thickness of sidewall films 17 becomes thicker toward the upward direction in the Z direction as viewed in FIG. 3. Further, when viewed in cross section, the outline of sidewall films 17 is curved and the upper end portion (uppermost portion) has the maximum thickness. Sidewall films 17 may be described as being formed in the shape of a collar along the side surface of interlayer insulating layer 14.

Thus, in the cross section taken along the width direction of bit line BL (the X direction in FIG. 3), the conductor layer portion (barrier metal 18 and metal film 20) of bit line contact CB is shaped so as to be narrowed toward its upper portion. In other words, in the cross section, the width of the upper portion of bit line contact CB is reduced toward the upper portion (the Z direction in FIG. 3). In the cross section, the thickness of sidewall films 17 increases toward upward direction in the Z direction as viewed in FIG. 3. The side surfaces of bit line contact CB contact the side surfaces of insulating film 12, interlayer insulating layer 14, and sidewall films 17. Further, the width in the X direction of the portion of bit line contact CB contacting the side surface of sidewall films 17 is narrowed.

As described above, sidewall films 17 shaped like a collar, is formed along the upper side surfaces of the inner walls of bit line BL trenches and along the upper side surfaces of the inner walls of bit line contacts CB. Thus, in the cross section taken along the width direction of bit line BL (the X direction in FIG. 3), width W1 of bit line contact CB (the width of the conductor layer portion of bit line contact CB) and width W2 of bit line BL (the width of the conductor layer portion of bit line BL) are reduced toward their upper portions. Distance D1 between adjacent bit line contact CB and bit line BL (that is, the distance between the conductor layer portions (barrier metal 18 and metal film 20) of bit line contact CB and bit line BL) becomes larger as compared to the case where sidewall film 17 is absent. Thus, distance D1 between the adjacent bit line contact CB and bit line BL can be secured to isolate each other. As a result, it is possible to suppress the leakage current between the adjacent bit line contact CB and bit line BL.

Further, in the cross section taken along the width direction of bit line BL (the X direction in FIG. 3), distance D2 between adjacent bit lines BL (that is, the distance between the conductor layer portions of adjacent bit lines BL) becomes larger as compared to the case where sidewall film 17 is absent. Thus, distance between the adjacent bit lines BL can be secured to isolate each other. As a result, it is possible to suppress the leakage current between the adjacent bit lines BL. Further, it is possible to improve the breakdown voltage between the adjacent bit lines BL.

### (Manufacturing Method)

Next, a description is given on the manufacturing process flow of a semiconductor storage device of the present embodiment with reference to FIGS. 3 to 8. FIGS. 3 to 8 illustrate the manufacturing process flow of a NAND flash memory device of the present embodiment and are vertical cross sectional views illustrating examples of cross sectional structures of one phase of the manufacturing process flow. FIG. 3 to 8 are schematic examples of cross sectional structures taken along line 3-3 of FIG. 2 and illustrate the cross sectional structures of one phase of the manufacturing process flow of the region for forming the drain-side bit line contact CB.

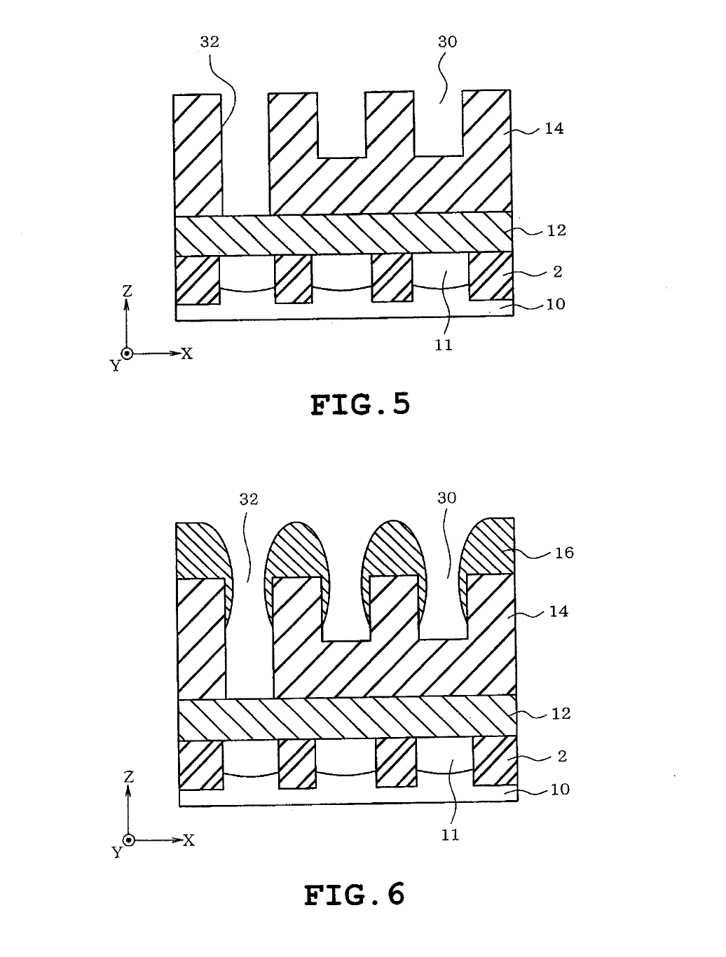

As shown in FIG. 4, semiconductor substrate 10 is prepared which has element isolation region 2 and impurity region 11 formed in its surface. A silicon substrate lightly doped with impurities may be used, for example, as semiconductor substrate 10. Element isolation region 2 may be formed by providing a trench in semiconductor substrate 10 and filling the trench with a silicon oxide film. Impurity region 11 may be formed by introducing impurities such as phosphorous or arsenic by ion implantation, for example, into semiconductor substrate 10.

Then, insulating film 12 is formed above semiconductor substrate 10. A silicon nitride film formed, for example, by CVD (Chemical Vapor Deposition) may be used as insulating film 12. LP (Low Pressure) CVD may be used, for example, to form a dense silicon nitride film.

Then, interlayer insulating layer 14 is formed above insulating film 12. Interlayer insulating layer 14 may be formed, for example, by CVD (Chemical Vapor Deposition) using TEOS (Tetraethyl orthosilicate, tetraethoxysilane) as a source gas.

Then, contact hole 32 and wiring trench 30 are formed using a dual damascene technique. First, contact hole 32 is formed by lithography and RIE (Reactive Ion Etching). Anisotropic etching conditions, for example, may be used in the RIE. The etching may be stopped on the surface of insulating film 12.

Then, wiring trenches 30 are formed by lithography and RIE. Anisotropic etching conditions, for example, may be used in the RIE. The etching is carried out about midway through interlayer insulating layer 14 in order to form a trench having a predetermined thickness in interlayer insulating layer 14. The etching may be carried out, for example, for a specified time period.

Wiring trenches 30 and contact hole 32 are formed in interlayer insulating layer 14 by the etching step. Further, the upper portion of contact hole 32 is formed in one with wiring trenches 30 (as shown in FIG. 2).

An example of the so called via-first dual damascene technique was described above in which formation of contact hole 32 is followed by formation of wiring trenches 30. However, this is merely an example. The so called trench-first dual damascene technique may be used in which formation of wiring trenches 30 are followed by formation of contact hole 32.

Then, cap films 16 are formed as shown in FIG. 6. A material including the same component as insulating film 12 may be used as cap films 16. A silicon nitride film formed, for example, by plasma CVD may be used as cap film 16. Cap film 16 is formed under conditions providing poor coverage. As a result, cap films 16 are formed along the upper side surfaces of wiring trench 30 and contact hole 32 and the upper surface of interlayer insulating layer 14, and not along the lower side surfaces and bottom portions of wiring trench 30 and contact hole 32. Cap films 16 are formed at a thickness that does not close the openings of wiring trenches 30 and contact hole 32. Thus, the adjacent cap films 16 are separated from each other. Because cap films 16 are formed under conditions providing poor coverage, the thickness of cap film 16 formed along the upper surface of interlayer insulating layer 14 is greater than the thickness of cap film 16 formed at wiring trench 30 and contact hole 32. The lower side surfaces and bottom portions of wiring trenches 30 and contact hole 32 are not covered by cap film 16 and thus, their surfaces are exposed.

As shown in FIG. 7, insulating film 12 is etched using RIE carried out under anisotropic conditions. The etching of insulating film 12 may be stopped on the surface of semiconductor substrate 10. As a result, contact hole 32 reaches impurity region 11 and impurity region 11 is exposed by contact hole 32. The etching also etches cap films 16 at the same time to etch back cap films 16. Thus, cap films 16 remain only along the upper side surfaces of wiring trenches 30 and contact hole 32 to form sidewall films 17. In the cross section shown in FIG. 7, sidewall films 17 are curved and thickness of sidewall films 17 is gradually increased toward the upward direction from the lower side surfaces of wiring trench 30 and contact hole 32. Further, the thickness of sidewall films 17 in the X direction is maximized at a portion located at a height slightly lower than the surface of interlayer insulating layer 14. The etching rate of insulating film 12 and the etching rate of cap films 16 may be specified so as to be substantially equal or so that the etching rate of cap films 16 is higher than the etching rate of insulating film 12. As described above, insulating film 12 is rendered dense by LPCVD, whereas sidewall film 17 is rendered sparse by plasma CVD. It is thus, possible to render the etching rate of insulating film 12 to be substantially equal to the etching rate of cap films 16 or lower than the etching rate of cap films 16. As a result, it is possible remove cap films 16 disposed above the upper surface of interlayer insulating layer 14 more reliably. By removing cap film 16 disposed above the upper surface of interlayer insulating layer 14, it is possible to prevent the polishing from being stopped on the remaining cap film 16 in the later described CMP (Chemical Mechanical Polishing) processing step.

As shown in FIG. 8, barrier metal 18 is formed inside wiring trench 30 and contact hole 32 and along the surface of interlayer insulating layer 14. Then, metal film 20 is formed so as to fill wiring trenches 30 and contact hole 32 and further cover the upper surface of interlayer insulating layer 14. A stack of titanium (Ti) and titanium nitride (TiN) films, for example, may be used as barrier metal 18. Titanium and titanium nitride may be formed by CVD for example. Tungsten (W) may be used as metal film 20 for example. Tungsten may be formed by CVD for example.

Then, as shown in FIG. 3, metal film 20 and barrier metal 18 disposed along the surface of interlayer insulating layer 14 is polished away by CMP. Further, metal film 20, barrier metal 18, sidewall film 17, and interlayer insulating layer 14 are polish removed so that at least sidewall films 17 formed at the upper portions of contact hole 32 and wiring trenches 30 remain. Preferably, metal film 20, barrier metal 18, sidewall film 17, and interlayer insulating layer 14 are polish removed to the vicinity of the location where thickness of sidewall film 17 in the X direction is maximized.

As are result, bit line contact CB and bit lines BL are isolated from one another and their upper surfaces are planarized. It is possible to form bit line contact CB and bit lines BL of the present embodiment by the above described process flow.

It is possible to reduce the size of the opening at the upper portion of bit line contact CB and the upper portion of bit lines BL by the above described process flow. As a result, it is possible to secure and increase the distance between bit line contact CB and bit line BL or between the adjacent bit lines BL at their upper surface portions. Thus, it is possible to reduce or suppress the leakage current between bit line contact CB and bit line BL or between the adjacent bit lines BL and improve the breakdown voltage.

### Other Embodiments

The following modifications may be made to the embodiment described above.

In the above described embodiment, an example of bit line contact CB of NAND flash memory was given in which the contact hole was connected to impurity region 11 provided in the surface of semiconductor substrate 10. In an alternative embodiment, the contact hole may be connected to a wiring, for example. For example, the contact hole may be connected to a gate electrode of a transistor. In such case, the gate electrode may include materials such as cobalt silicide (CoSi) or nickel silicide (Nisi).

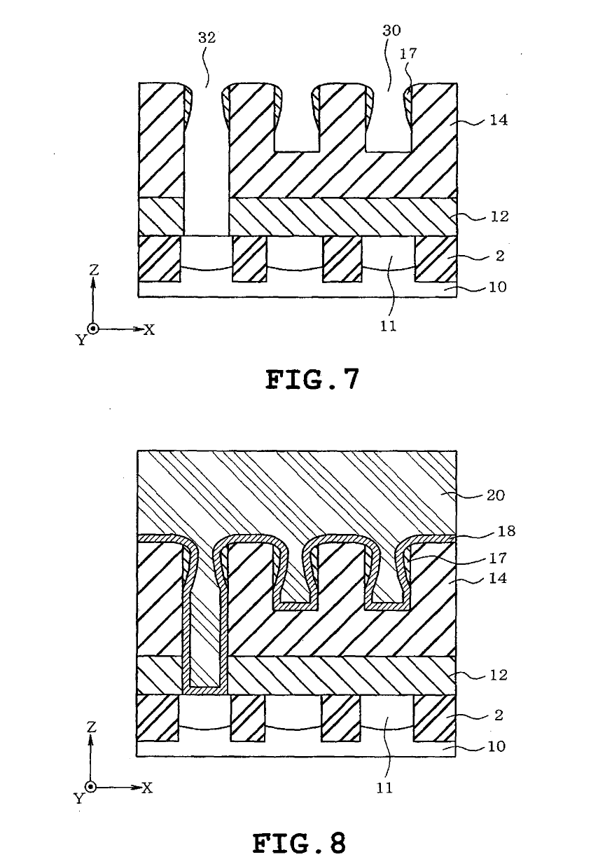

Further, contact hole 32 and wiring trench 30 often have a reverse tapered shape. Thus, bit line contact CB and bit line BL may have a reverse tapered shape as shown in FIG. 9. The upper portions of bit line contact CB and bit line BL are narrowed toward their upper potions in such case also. It is possible to obtain the effects similar to those of the above described embodiment in such case also.

The above described embodiment was described through an example of NAND flash memory application but other embodiments may be described through examples of other nonvolatile semiconductor storage devices such as NOR flash memory device or EPROM, or semiconductor storage devices such as DRAM or SRAM, or further through logic semiconductor devices such as microcomputers.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
an insulating layer having a trench;
a first insulating film formed only along an upper portion of the trench, a thickness of the first insulating film increasing in an upward direction from a bottom portion of the trench; and
a first conductor layer formed in the trench, a side surface of the first conductor contacting the insulating layer and the first insulating film.

2. The device according to claim 1, wherein the first conductor layer has a narrowed shape at the upper portion of the trench.

3. The device according to claim 1, wherein the thickness of the first insulating film is maximized at an upper end portion of the first insulating film.

4. The device according to claim 1, wherein an outline of a cross section of the first insulating film is curved.

5. The device according to claim 1, further comprising:
a contact hole disposed in the insulating layer adjacent to the trench,
a second conductor layer,
a second insulating film formed only along an upper portion of a sidewall of the contact hole, and
a third conductor layer formed in the contact hole, a bottom surface of the third conductor layer contacting the second conductor layer and a side surface of the third conductor layer contacting the insulating layer and the second insulating film.

6. The device according to claim 5 including two or more third conductor layers disposed in a zigzag in a planar layout.

7. The device according to claim 5 further comprising a third insulating film between the second conductor layer and the insulating layer,
wherein the third conductor layer extends through the insulating layer and the third insulating film and is connected to a surface of the second conductor layer, and
wherein the first insulating film and the second insulating film include a same component as the third insulating film.

8. The device according to claim 7, wherein the first insulating film and the second insulating film are sparse compared to the third insulating film.

9. A method of manufacturing a semiconductor device comprising:
forming a first conductor layer above a semiconductor substrate;
forming a first insulating film above the first conductor layer;
forming an insulating layer above the first insulating film;
forming a contact hole extending through the insulating layer and reaching an upper surface of the first insulating film;
forming a second insulating film only along an upper portion of a side surface of the contact hole and an upper surface of the insulating layer;
selectively removing the first insulating film at a bottom portion of the contact hole so as to expose a surface of the first conductor layer by the contact hole, and removing the second insulating film so that the second insulating film remains at least along the upper portion of the side surface of the contact hole;
forming a second conductor layer filling the contact hole and covering an upper surface of the insulating layer; and
removing the second conductor layer formed above the insulating layer so that the second insulating film formed along the upper portion of the side surface of the contact hole remains.

10. The method according to claim 9, wherein forming the second insulating film uses a plasma chemical vapor deposition.

11. The method according claim 10, wherein forming the first insulating film uses a low pressure chemical vapor deposition.

12. The method according to claim 9, wherein the first insulating film and the second insulating film are removed by etching, and wherein the etching of the first insulating film and the second insulating film are carried out so that an etching rate of the second insulating film is equal to or higher than an etching rate of the first insulating film.

13. The method according to claim 9, wherein forming the second insulating film forms the second insulating film so that a thickness of the second insulating film above the insulating layer is greater than a thickness of the second insulating film along the side surface of the contact hole.

14. The method according to claim 9, wherein removing the second conductor layer removes the insulating layer, the second insulating film, and the second conductor layer until the portion of the second insulating film having the maximum thickness is reached.
